(19) United States
(12) Patent Application Publication
(10) Pub. No.: US 2018/0323246 A1
(43) Pub. Date: Nov. 8, 2018

(54) ORGANIC LIGHT-EMITTING DIODE DISPLAY PANEL AND MANUFACTURING METHOD THEREOF

(71) Applicant: SHENZHEN CHINA STAR OPTOELECTRONICS TECHNOLOGY CO., LTD., Shenzhen, Guangdong (CN)

(72) Inventors: Xiaoxing ZHANG, Shenzhen, Guangdong (CN); Yuan-Jun HSU, Shenzhen, Guangdong (CN)

(73) Assignee: Shenzhen China Star Optoelectronics Technology Co., Ltd., Shenzhen, Guangdong (CN)

(21) Appl. No.: 15/541,746

(22) PCT Filed: May 27, 2017
(86) PCT No.: PCT/CN2017/086234

§ 371 Date: Jul. 6, 2017

(30) Foreign Application Priority Data
May 2, 2017 (CN) 201710302087.1

(51) Int. Cl. H01L 27/32

(52) U.S. Cl. CPC H01L 27/3258; H01L 27/1218; H01L 2227/323; H01L 27/3262

(57) ABSTRACT

The present invention provides an organic light-emitting display panel and manufacturing method thereof. The method is to use the feature that silicon nitride has more hydrogen atoms, so that the oxide semiconductor in contact with the part of oxide semiconductor pattern layer with conductor characteristics, can be continuously doped with hydrogen atoms to hold conductor characteristics, and the contact impedance between the part of oxide semiconductor pattern layer and the source and the drain can be continuously maintained at a low state to achieve the function of TFT.

### FIELD OF THE INVENTION

The present invention relates to a technology of display, and more particularly, to an organic light-emitting display panel and manufacturing method thereof.

### DESCRIPTION OF PRIOR ART

Currently, because oxide semiconductor thin film transistor (TFT) with the top gate structure has a smaller parasitic capacitance, the size of TFT can be smaller to be a better choice for organic light-emitting display (OLED) drive. However, the oxide semiconductor in contact with a source and a drain, need to be processed to be converted into conductor in the manufacturing process of the oxide semiconductor TFT with the top gate structure, thereby the contact impedance of the source and the drain is reduced, and the switching function of the TFT is achieved.

In the prior art, to convert the oxide semiconductor in contact with the source and the drain into a conductor, is generally processed by hydrogen plasma or argon plasma. However, because the OLED display panel has another annealing process after arranging the TFT, the annealing processes will case the conductive oxide to be converted back into semiconductor, so that the contact impedance of the source and the drain will become larger, the TFT characteristics is reduced, and even the TFT losses its switching function.

### SUMMARY OF THE INVENTION

The present invention is mainly to provide an OLED display panel and a manufacturing method thereof, to solve the problem that the contact impedance of source and drain become larger because a part of oxide semiconductor with conductor characteristics is converted into back to semiconductor in the OLED display panel manufacturing process.

In order to solve the above-mentioned technical problem, a technical solution adopted by the present invention is: providing a method of manufacturing an organic light-emitting diode display panel, wherein the method comprises: depositing a buffer layer on a substrate and arranging an oxide semiconductor pattern layer, a gate insulating layer, and a gate pattern layer stacked sequentially on the buffer layer; arranging a dielectric layer for covering the oxide semiconductor pattern layer, the gate insulating layer, and the gate pattern layer on the buffer layer, and the dielectric layer comprises a silicon nitride layer in contact with the oxide semiconductor pattern layer; annealing the dielectric layer, and the silicon nitride layer cases a part of oxide semiconductor pattern layer to have conductor characteristics during the annealing process; arranging a source and a drain in contact with the part of oxide semiconductor pattern layer, with conductor characteristics; wherein the buffer layer comprises a silicon oxide layer in contact with the oxide semiconductor pattern layer; wherein the gate insulating layer comprises a third part and a fourth part, the fourth part is adjacent to the third part, the third part is arranged opposite to the gate pattern layer, the fourth part is in contact with the nitrogen silicon layer.

In order to solve the above-mentioned technical problem, a further technical solution adopted by the present invention is: providing a method of manufacturing an organic light-emitting diode display panel, wherein the method comprises: depositing a buffer layer on a substrate and arranging an oxide semiconductor pattern layer, a gate insulating layer, and a gate pattern layer stacked sequentially on the buffer layer; arranging a dielectric layer for covering the oxide semiconductor pattern layer, the gate insulating layer, and the gate pattern layer on the buffer layer, and the dielectric layer comprises a silicon nitride layer in contact with the oxide semiconductor pattern layer; annealing the dielectric layer, and the silicon nitride layer cases a part of oxide semiconductor pattern layer to have conductor characteristics during the annealing process; arranging a source and a drain are in contact with the part of oxide semiconductor pattern layer, with conductor characteristics.

In order to solve the above-mentioned technical problem, a further technical solution adopted by the present invention is: providing an organic light-emitting diode display panel, wherein the display panel comprises: depositing a buffer layer on a substrate and arranging an oxide semiconductor pattern layer, a gate insulating layer, and a gate pattern layer stacked sequentially on the buffer layer, wherein a part of oxide semiconductor pattern layer has conductor characteristics; a dielectric layer covers the oxide semiconductor pattern layer, the gate insulating layer, and the gate pattern layer, and the dielectric layer comprises a silicon nitride layer in contact with the oxide semiconductor pattern layer; a source and a drain are in contact with the part of oxide semiconductor pattern layer, with conductor characteristics.

The present invention can be concluded with the following advantages, the present invention is different from the prior art of a buffer layer deposited on a substrate and an oxide semiconductor pattern layer, a gate insulating layer, and a gate pattern layer are stacked sequentially on the buffer layer; arranging a dielectric layer for covering the oxide semiconductor pattern layer, the gate insulating layer, and the gate pattern layer on the buffer layer, and the dielectric layer comprises a silicon nitride layer in contact with the oxide semiconductor pattern layer; annealing the dielectric layer, and the silicon nitride layer cases a part of oxide semiconductor pattern layer to have conductor characteristics during the annealing process; a method of arranging a source and a drain are in contact with the part of oxide semiconductor pattern layer, with conductor characteristics, wherein the method is to use the feature that silicon nitride has more hydrogen atoms, so that the oxide semiconductor in contact with the part of oxide semiconductor pattern layer with conductor characteristics, can be continuously doped with hydrogen atoms to hold conductor characteristics, and the contact impedance between the part of oxide semiconductor pattern layer and the source and the drain can be continuously maintained at a low state to achieve the function of TFT.

### BRIEF DESCRIPTION OF DRAWINGS

FIG. 1 is a flow chart of method of manufacturing an organic light-emitting diode display panel of an embodiment in the present invention;

FIG. 2 is a structural illustration of an embodiment made in accordance to an organic light-emitting diode display panel in the present invention;

FIG. 3 is a specific flow chart of step S11 in FIG. 1; and

FIG. 4 is a specific flow chart of step S14 in FIG. 1.

### DESCRIPTION OF PREFERRED EMBODIMENT

Technical implementation will be described below clearly and fully by combining with drawings made in accordance with an embodiment in the present invention.

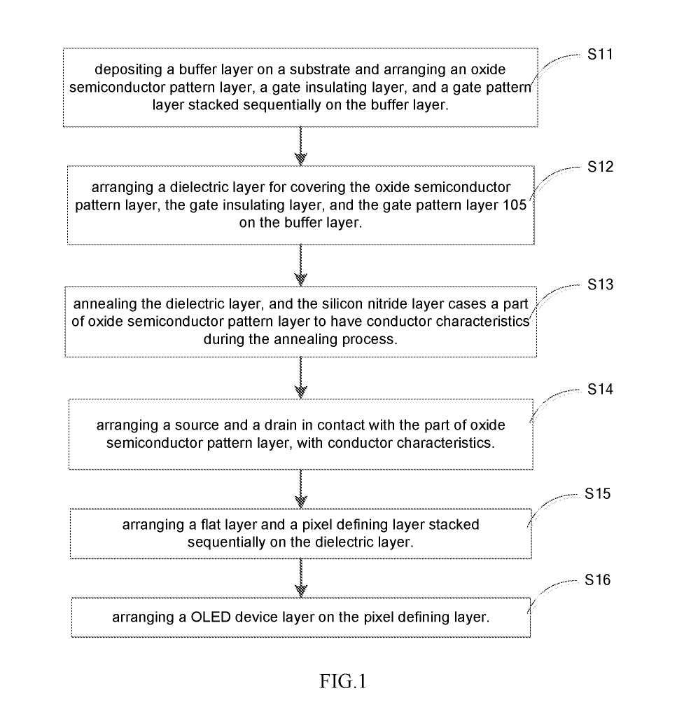

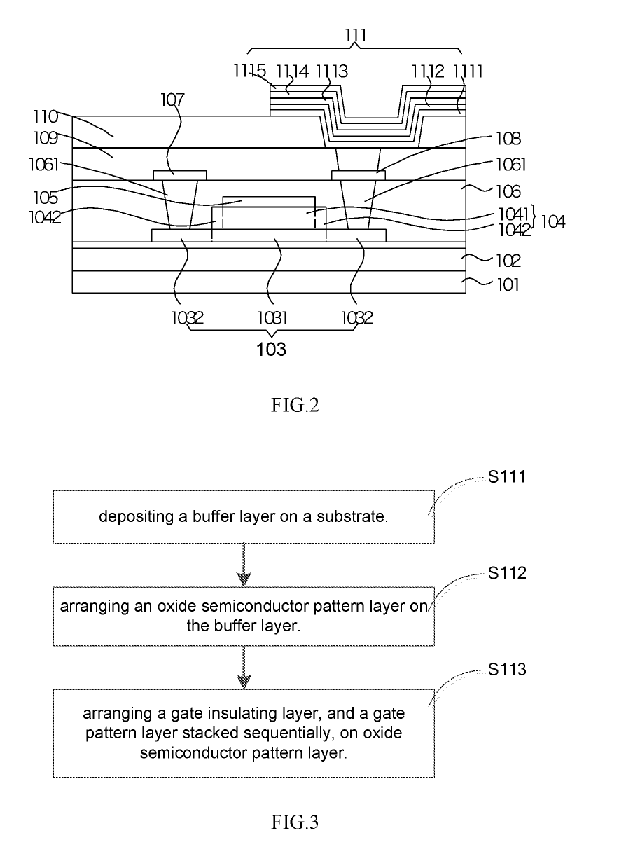

Referring to FIG. 1 and FIG. 2, the method of manufacturing an organic light-emitting diode display panel of the present invention, which comprises:

S11: depositing a buffer layer 101 on a substrate 102 and arranging an oxide semiconductor pattern layer 103, a gate insulating layer 104, and a gate pattern layer 105 stacked sequentially on the buffer layer 102.

Referring to FIG. 3, the step S11 may specifically include:

S111: depositing a buffer layer 101 on a substrate 102.

Specifically, before depositing the buffer layer 102, cleaning the substrate 101, then the buffer layer 102 may be deposited on the substrate 101 by physical vapor deposition method or plasma vapor deposition method, wherein it may deposit a silicon oxide layer on the substrate 101 as a buffer layer 102, or it may be also to deposit a silicon nitride layer on the substrate 101 first, and then depositing a silicon oxide layer with a thickness of not less than 3000 Å on the silicon nitride layer, so that the silicon nitride layer and the silicon oxide layer form a buffer layer 102 collectively.

Wherein the substrate 101 may be a glass substrate, or a silicon substrate, including, but not limited to.

S112: arranging an oxide semiconductor pattern layer 103 on the buffer layer 102.

Specifically, arranging an oxide semiconductor pattern layer 103 on the silicon oxide layer on the buffer layer 102, it may deposit an oxide semiconductor with a thickness of 400 to 600 Å on the silicon oxide layer in the buffer layer 102, and then processing photoresist coating, exposure, development, and peeling of the photolithography process to form an oxide semiconductor pattern layer, because the silicon oxide does not contain hydrogen atoms, in this step S112, the oxide semiconductor pattern layer is not converted into conductor.

Wherein the oxide semiconductor pattern layer 103 comprises a first part 1031 and a second part 1032, the second part 1032 is adjacent to the first part 1031. In the figure of the present embodiment, the second part 1032 is located on opposite sides of the first part 1031.

Preferably, the oxide semiconductor is indium gallium zinc oxide (IGZO.)

S113: arranging a gate insulating layer 104, and a gate pattern layer 105 stacked sequentially, on oxide semiconductor pattern layer 103.

Wherein the gate insulating layer 104 is arranged opposite to the first part 1031 of the oxide semiconductor pattern layer 103, the gate insulating layer 104 comprises a third part 1041 and a fourth part 1042, the fourth part 1042 is adjacent to the third part 1041. In the figure of the present embodiment, the fourth part 1042 is located on opposite sides of the third part 1041 and the third part 1041 is arranged opposite to the gate pattern layer 105.

Specifically, it may use the physical vapor deposition method or plasma vapor deposition method to deposit a silicon oxide layer with a thickness of 1000 to 2000 Å on the buffer layer 102, and the silicon oxide layer covers the oxide semiconductor pattern layer 103, and then depositing a metal layer on the silicon oxide layer, after photoresist coating, exposure, and development, etching the metal layer and the silicon oxide layer simultaneously, to form the gate pattern layer 105 and the gate insulating layer 104. During the etching process, as shown in FIG. 2, suitable etching conditions case that the opposite sides of the gate insulating layer 104 extends beyond the gate pattern layer 105. The parts of the opposite sides of the gate insulating layer extending beyond the gate pattern layer are the forth part 1042, and the part in the middle, arranging opposite to the gate pattern layer 105 is the third part 1041.

Wherein the metal layer is molybdenum, aluminum or copper metal layer, including, but not limited to.

Preferably, the length of the fourth part 1042 is 0.3 μm to 1 μm.

In other embodiments, the gate insulating layer 104 and the gate pattern layer 105 may be formed in two steps, respectively. It may deposit the silicon oxide layer on the buffer layer 102 first, processing photoresist coating, exposure, development, etching, and peeling, to form the gate insulating layer 104 arranged opposite to the oxide semiconductor pattern layer 103. Then depositing metal layer on the gate insulating layer 104, processing photoresist coating, exposure, development, etching, and peeling again, to form the gate pattern layer 105, and case that the gate pattern layer 105 is arranged opposite to the third part 1041 of the gate insulating layer 104.

S12: arranging a dielectric layer 106 for covering the oxide semiconductor pattern layer 103, the gate insulating layer 104, and the gate pattern layer 105 on the buffer layer 102.

Wherein the dielectric layer 106 comprises a silicon nitride layer in contact with the oxide semiconductor pattern layer 103.

Specifically, it may use the physical vapor deposition method or plasma vapor deposition method to deposit a silicon nitride layer with a thickness of 4000 to 5000 Å on the buffer layer 102 to form the dielectric layer 106, or it may deposit a silicon nitride layer with a thickness of 3000 Å on the buffer layer 102, and then deposit a silicon oxide layer with a thickness of 3000 Å, so that the silicon nitride layer and the silicon oxide layer form a dielectric layer 106 collectively. It should be notice that by the above-mentioned steps, the thickness of the silicon nitride layer in the dielectric layer 106 is larger than the thickness of the oxide semiconductor pattern layer 103 and the thickness of the gate insulating layer 104, so that the dielectric layer 106 can contact the second part 1032 of the oxide semiconductor pattern layer 103 and the fourth part 1042 of the gate insulating layer 104.

S13: annealing the dielectric layer 106, and the silicon nitride layer cases a part of oxide semiconductor pattern layer to have conductor characteristics during the annealing process.

Specifically, because the silicon nitride layer contains hydrogen atoms, during the annealing process of the dielectric layer 106, under high temperature, the hydrogen atoms are diffused to the oxide semiconductor pattern layer 103 where in the bottom as shown in FIG. 2. During the diffusion process, because the second part 1032 of the oxide semiconductor pattern layer 103 is in contact with the silicon nitride layer, the hydrogen atoms diffuse to the second part 1032 so that the second part 1032 is doped with hydrogen atoms to have conductor characteristics.

Wherein, because the gate insulating layer 104 is a silicon oxide layer, the first part 1031 arranged opposite the gate insulating layer 104 is protected by the gate insulating layer 104, to prevent the diffusion of hydrogen atoms into the first part 1031, So that after the annealing, the first part 1031 still holds semiconductor characteristics. And according to the above-described step S113, the gate insulating layer 104 is larger in size on the cross-section than the gate pattern layer 105, to further prevent the hydrogen atoms in the silicon nitride layer from diffusing down to the first part 1031, so that the first part 1031 still holds semiconductor characteristics.

S14: arranging a source 107 and a drain 108 in contact with the part of oxide semiconductor pattern layer, with conductor characteristics.

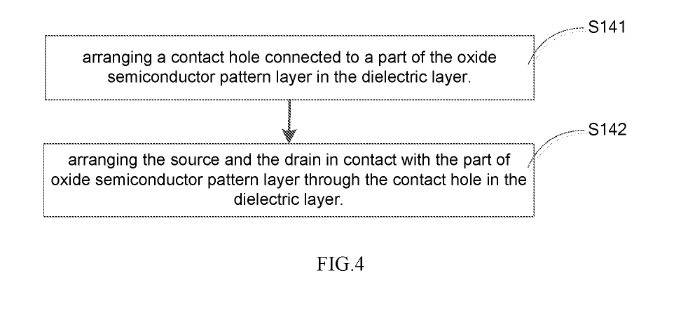

Referring to FIG. 4, the step S14 may specifically include:

S141: arranging a contact hole 1061 connected to a part of the oxide semiconductor pattern layer in the dielectric layer 106.

Specifically, a patterned contact hole may be formed by photoresist coating and exposure, then processed dry etching, the contact hole 1061 may be obtained after removal.

Wherein both the dielectric layer 106 and the second part 1032 on both sides of the oxide semiconductor pattern layer 103, have a contact hole 1061.

S142: arranging the source 107 and the drain 108 in contact with the part of oxide semiconductor pattern layer through the contact hole 1061 in the dielectric layer 106.

Specifically, it may deposit metal on the dielectric layer 106 and the contact hole 1061 to form a metal layer by physical vapor deposition method, then depositing a photoresist layer on the deposited metal layer, and processing exposure, development, etching, and peeling, to form a patterned source 107 and drain 108. Because the contact hole 1061 is connected to the second part 1032 of the oxide semiconductor pattern layer 103, so that the patterned source 107 and the drain 108 are in contact with the second part 1032 of the oxide semiconductor pattern layer 103.

Further, the present embodiment further comprises:

S15: arranging a flat layer 109 and a pixel defining layer 110 stacked sequentially on the dielectric layer 106.

Specifically, it may deposit a silicon nitride layer or a silicon oxide layer on the dielectric layer 106 by physical vapor deposition method or a plasma vapor deposition method, to form the flat layer 109, then depositing a silicon nitride layer or a silicon oxide layer on the flat layer 109, and processing exposure, development, and, etching, to form a pixel light emitting region. The silicon nitride layer or the silicon oxide layer with the pixel light emitting region is the pixel defining layer 110

S16: arranging a OLED device layer 111 on the pixel defining layer 110.

Specifically, arranging sequentially an anode layer 1111, an electron transport layer 1112, a light emitting layer 1113, a hole transport layer 1114, and a cathode layer 1115, at the position opposite to the pixel light emitting region on the pixel definition layer 110.

Further, referring to FIG. 2, the OLED display panel of the embodiment of the present invention, which comprises a buffer layer 102 deposited on a substrate 101; an oxide semiconductor pattern layer 103, a gate insulating layer 104, and a gate pattern layer 105 stacked sequentially on the buffer layer 102; a dielectric layer 106 covers the oxide semiconductor pattern layer 103, the gate insulating layer 104, and the gate pattern layer 105; and a source 107 and a drain 108 are in contact with the oxide semiconductor pattern layer 103.

Wherein the oxide semiconductor pattern layer 103 comprises a first part 1031 and a second part 1032, the second part 1032 is adjacent to the first part 1031, the first part 1031 is arranged opposite to the gate insulating layer 104, the second part 1032 has conductor characteristics.

Specifically, the dielectric layer 106 comprises a silicon nitride layer in contact with the oxide semiconductor pattern layer 103. Because the silicon nitride layer contains hydrogen atoms, during the manufacturing process, the hydrogen atoms in the silicon nitride layer diffuse to the oxide semiconductor pattern layer 103, so as the second part 1032 in contact with the silicon nitride layer, is doped with the hydrogen atoms, thereby the second part 1032 has conductor characteristics. The first part 1031 is arrange opposite to the gate insulating layer 104 and is protected by the gate insulating layer 104 to prevent the first part 1031 from doping the hydrogen atoms, so that the first part 1031 still holds semiconductor characteristics.

Further, the display panel of the present embodiment further comprises a flat layer 109, a pixel defining layer 110, and an OLED device layer 111 stacked sequentially on the dielectric layer 106.

Each of the layers in the present embodiment can be manufactured by the steps corresponding to the above-described methods, therefore no additional description is given herebelow.

The present invention is different from the prior art of a buffer layer deposited on a substrate and an oxide semiconductor pattern layer, a gate insulating layer, and a gate pattern layer are stacked sequentially on the buffer layer; arranging a dielectric layer for covering the oxide semiconductor pattern layer, the gate insulating layer, and the gate pattern layer on the buffer layer, and the dielectric layer comprises a silicon nitride layer in contact with the oxide semiconductor pattern layer; annealing the dielectric layer, and the silicon nitride layer cases a part of oxide semiconductor pattern layer to have conductor characteristics during the annealing process; a method of arranging a source and a drain are in contact with the part of oxide semiconductor pattern layer, with conductor characteristics, wherein the method is to use the feature that silicon nitride has more hydrogen, so that the oxide semiconductor in contact with the part of oxide semiconductor pattern layer with conductor characteristics, can be continuously doped with hydrogen to hold conductor characteristics, and the contact impedance between the part of oxide semiconductor pattern layer and the source and the drain can be continuously maintained at a low state to achieve the function of TFT.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

1. A method of manufacturing an organic light-emitting diode display panel, wherein the method comprises:
depositing a buffer layer on a substrate and arranging an oxide semiconductor pattern layer, a gate insulating layer, and a gate pattern layer stacked sequentially on the buffer layer;
arranging a dielectric layer for covering the oxide semiconductor pattern layer, the gate insulating layer, and the gate pattern layer on the buffer layer, and the dielectric layer comprising a silicon nitride layer in contact with the oxide semiconductor pattern layer;
annealing the dielectric layer, and the silicon nitride layer casing a part of oxide semiconductor pattern layer to have conductor characteristics during the annealing process;
arranging a source and a drain in contact with the part of oxide semiconductor pattern layer, with conductor characteristics;
wherein the buffer layer comprises a silicon oxide layer in contact with the oxide semiconductor pattern layer;
wherein the gate insulating layer comprises a third part and a fourth part, the fourth part is adjacent to the third part, the third part is arranged opposite to the gate pattern layer, the fourth part is in contact with the nitrogen silicon layer.

2. The method as recited in claim 1, wherein the oxide semiconductor pattern layer comprises a first part and a second part, the second part is adjacent to the first part, the first part is arranged opposite to the gate insulating layer, the second part is in contact with the silicon nitride layer, and the above-mentioned description of annealing the dielectric layer, and the silicon nitride layer casing a part of oxide semiconductor pattern layer to have conductor characteristics during the annealing process, which comprises:
annealing the dielectric layer, and the silicon nitride layer casing the second part in contact with the silicon nitride layer, to have conductor characteristics during the annealing process.

3. The method as recited in claim 2, wherein the silicon nitride layer contains hydrogen atoms, above-mentioned description of annealing the dielectric layer, and the silicon nitride layer casing the second part in contact with the silicon nitride layer, to have conductor characteristics during the annealing process, which comprises:
during the annealing process, the hydrogen atoms in the silicon nitride layer diffusing to the oxide semiconductor pattern layer, so as the second part in contact with the silicon nitride layer, doped with the hydrogen atoms, thereby having conductor characteristics.

4. The method as recited in claim 3, wherein the gate insulating layer is a silicon oxide layer, the gate insulating layer and the first part arranged opposite to the gate insulating layer hold semiconductor characteristics after annealing.

5. The method as recited in claim 1, wherein the above-mentioned description of arranging a source and a drain in contact with the part of oxide semiconductor pattern layer, with conductor characteristics, which comprises:
arranging a contact hole connected to a part of the oxide semiconductor pattern layer in the dielectric layer;
arranging the source and the drain in contact with the part of oxide semiconductor pattern layer through the contact hole in the dielectric layer.

6. A method of manufacturing an organic light-emitting diode display panel, wherein the method comprises:
depositing a buffer layer on a substrate and arranging an oxide semiconductor pattern layer, a gate insulating layer, and a gate pattern layer stacked sequentially on the buffer layer;
arranging a dielectric layer for covering the oxide semiconductor pattern layer, the gate insulating layer, and the gate pattern layer on the buffer layer, and the dielectric layer comprising a silicon nitride layer in contact with the oxide semiconductor pattern layer;
annealing the dielectric layer, and the silicon nitride layer casing a part of oxide semiconductor pattern layer to have conductor characteristics during the annealing process;
arranging a source and a drain in contact with the part of oxide semiconductor pattern layer, with conductor characteristics.

7. The method as recited in claim 6, wherein the oxide semiconductor pattern layer comprises a first part and a second part, the second part is adjacent to the first part, the first part is arranged opposite to the gate insulating layer, the second part is in contact with the silicon nitride layer, and the above-mentioned description of annealing the dielectric layer, and the silicon nitride layer casing a part of oxide semiconductor pattern layer to have conductor characteristics during the annealing process, which comprises:
annealing the dielectric layer, and the silicon nitride layer casing the second part in contact with the silicon nitride layer, to have conductor characteristics during the annealing process.

8. The method as recited in claim 2, wherein the silicon nitride layer contains hydrogen atoms, above-mentioned description of annealing the dielectric layer, and the silicon nitride layer casing the second part in contact with the silicon nitride layer, to have conductor characteristics during the annealing process, which comprises:
during the annealing process, the hydrogen atoms in the silicon nitride layer diffusing to the oxide semiconductor pattern layer, so as the second part in contact with the silicon nitride layer, doped with the hydrogen atoms, thereby having conductor characteristics.

9. The method as recited in claim 8, wherein the gate insulating layer is a silicon oxide layer, the gate insulating layer and the first part arranged opposite to the gate insulating layer hold semiconductor characteristics after annealing.

10. The method as recited in claim 6, wherein the buffer layer comprises a silicon oxide layer in contact with the oxide semiconductor pattern layer;

11. The method as recited in claim 6, wherein the gate insulating layer comprises a third part and a fourth part, the fourth part is adjacent to the third part, the third part is arranged opposite to the gate pattern layer, the fourth part is in contact with the nitrogen silicon layer.

12. The method as recited in claim 6, wherein the above-mentioned description of arranging a source and a drain in contact with the part of oxide semiconductor pattern layer, with conductor characteristics, which comprises:
arranging a contact hole connected to a part of the oxide semiconductor pattern layer in the dielectric layer;
arranging the source and the drain in contact with the part of oxide semiconductor pattern layer through the contact hole in the dielectric layer.

13. An organic light-emitting diode display panel, wherein the display panel comprises:
depositing a buffer layer on a substrate and arranging an oxide semiconductor pattern layer, a gate insulating layer, and a gate pattern layer stacked sequentially on the buffer layer, wherein a part of oxide semiconductor pattern layer has conductor characteristics;
a dielectric layer covering the oxide semiconductor pattern layer, the gate insulating layer, and the gate pattern layer, and the dielectric layer comprising a silicon nitride layer in contact with the oxide semiconductor pattern layer;
a source and a drain in contact with the part of oxide semiconductor pattern layer, with conductor characteristics.

14. The display panel as recited in claim 13, wherein the oxide semiconductor pattern layer comprises a first part and a second part, the second part is adjacent to the first part, the first part is arranged opposite to the gate insulating layer, the second part is in contact with the silicon nitride layer, thereby the second part has conductor characteristics.

15. The display panel as recited in claim 14, wherein the silicon nitride layer contains hydrogen atoms, during the manufacturing process, the hydrogen atoms in the silicon nitride layer diffuse to the oxide semiconductor pattern layer, so as the second part in contact with the silicon nitride layer, is doped with the hydrogen atoms, thereby the second part has conductor characteristics.
